(19) United States
(12) Patent Application Publication
(10) Pub. No.: US 2019/0284684 A1
(43) Pub. Date: Sep. 19, 2019

(54) SUBLIMATED GAS SUPPLY SYSTEM AND SUBLIMATED GAS SUPPLY METHOD

(71) Applicant: L'Air Liquide, Société Anonyme pour I'Etude et I'Exploitation des Procédés Georges Claude, Paris (FR)

(72) Inventors: Chika SHIGAKI, Tsukuba (JP); Sayaka ISHIZUKA, Tsukuba (JP); Terumasa KOURA, Tsukuba (JP); Fumikazu NOZAWA, Sakura City (JP)

(21) Appl. No.: 16/302,398

(22) PCT Filed: Apr. 13, 2017
(86) PCT No.: PCT/EP2017/059036

§ 371 Date: Nov. 16, 2018

(30) Foreign Application Priority Data
May 20, 2016 (JP) 2016-101661

(51) Int. Cl. C23C 14/54; C23C 14/24

(52) U.S. Cl. CPC C23C 14/548; C23C 14/24

(57) ABSTRACT

Provided is a sublimated gas supply system capable of stabilizing the concentration of a sublimated gas of a solid material to be supplied and continuously supplying a sublimated gas with a stable concentration. The sublimated gas supply system includes a container; a heater for heating the container; a vacuum container configured so that a sublimated gas is introduced from the container in a vacuum state when a pressure measured with a container pressure gauge is the saturated vapor pressure of the sublimated gas; a flow amount control unit for controlling the flow amount of the dilution gas so that the concentration of the sublimated gas in the dilution gas inside the vacuum container is controlled to be a prescribed concentration based on the pressure inside the vacuum container when the sublimated gas is introduced into the vacuum container.

### BACKGROUND OF THE INVENTION

### Field of the Invention

The present invention relates to a sublimated gas supply system for supplying a sublimated gas of a solid material to a post process (for example, a film forming process) and a sublimated gas supply method.

### Description of the Related Art

In order to manufacture microelectronics devices such as semiconductor integrated devices and liquid crystal panels, it is necessary to forma film of various materials on a substrate. Further, in recent years, dry coating has been performed on various members to improve characteristics such as strength of the corresponding member. A PVD (physical vapor deposition) method, a CVD (chemical vapor deposition) method, an ALD (atomic layer deposition) method, etc. have been widely known as the film forming method or the coating method.

In order to respond to sever requirements for a film in accordance with the rapid progress of semiconductor industry, the vapor pressure of a precursor used for forming a film tends to be decreased. Examples of the precursor used for forming a film include organic metal compounds and inorganic compounds of aluminum, barium, bismuth, chromium, cobalt, copper, gold, hafnium, indium, iridium, iron, lanthanum, lead, magnesium, molybdenum, nickel, niobium, platinum, ruthenium, silver, strontium, tantalum, titanium, tungsten, yttrium, and zirconium. As a precursor for dry coating, an inorganic metal compound is generally used so as to form a carbon-free film.

Because these materials have a low vapor pressure, when these materials are solid materials, it is necessary to sublimate the solid materials to be supplied in introducing the solid materials into a film forming chamber. With a conventional method, a solid material that is set in a tray inside a container is heated, and a carrier gas is brought into contact with the solid material itself while saturated vapor is generated to supply the carrier gas containing a solid material component (sublimated gas) (for example, refer to Patent Document 1).

### PRIOR ART DOCUMENT

Patent Document

### Patent Document 1: JP-A-2013-28854

### SUMMARY OF THE INVENTION

However, with the conventional method, the amount of the sublimated gas changes when the remaining amount of the solid material changes, resulting in a change of the concentration of the sublimated gas in the gas supplied in a post process. Therefore, it is sometimes difficult to supply sublimated gas with a stable concentration.

Objects of the present invention are to provide a sublimated gas supply system and a sublimated gas supply method capable of stabilizing the concentration of a sublimated gas of a solid material to be supplied and continuously supplying a sublimated gas with a stable concentration.

One aspect of the present invention provides a sublimated gas supply system for supplying a sublimated gas produced from a solid material to a post process, the system including:

a container for storing a solid material;

a container heating unit for heating the container so that the sublimated gas of the solid material is produced;

a container pressure gauge for measuring a pressure inside the container;

a vacuum container configured so that the sublimated gas is introduced from the container in a state where a pressure of the sublimated gas is in a prescribed negative pressure range (in a vacuum state or a state of a prescribed negative pressure) when the pressure measured with the container pressure gauge is a saturated vapor pressure of the sublimated gas (or when the pressure of the sublimated gas inside the container is a prescribed value or more);

a dilution gas line for introducing a dilution gas into the vacuum container;

a pressure gauge for measuring a pressure inside the vacuum container;

a flow amount control unit (such as a mass flow controller) for controlling a flow amount of the dilution gas so that a concentration of the sublimated gas in the dilution gas inside the vacuum container is controlled to be a prescribed concentration based on (initial pressure before the sublimated gas is introduced into the vacuum container and) the pressure inside the vacuum container when the sublimated gas is introduced into the vacuum container;

a lead-out line for leading out the sublimated gas from the vacuum container into the post process when the concentration of the sublimated gas in the dilution gas reaches the prescribed concentration; and

a vacuum pump for making the vacuum container be in a vacuum state.

In the above description, the sublimated gas supply system may have a configuration in which the dilution gas is fed into the vacuum container every time the sublimated gas is fed from the container into the vacuum container to adjust the concentration of the sublimated gas, the sublimated gas (including the dilution gas) having a prescribed concentration is fed from the vacuum container into the post process, the vacuum container is then made to have a prescribed negative pressure state (such as a vacuum state), and the next sublimated gas is fed from the container into the vacuum container.

In the above description, the sublimated gas supply system may also have a configuration in which the dilution gas is fed into the vacuum container after the sublimated gas is fed from the container into the vacuum container two times or more to adjust the concentration of the sublimated gas, the sublimated gas (including the dilution gas) having a prescribed concentration is fed from the vacuum container into the post process, the vacuum container is then made to have a prescribed negative pressure state (such as a vacuum state), and the next sublimated gas is fed from the container into the vacuum container (two times or more).

According to this configuration, the sublimated gas produced when the solid material is heated is fed into the vacuum container in the negative pressure state. The dilution gas is added to the sublimated gas inside the vacuum container to dilute the sublimated gas to have a prescribed concentration. Accordingly, the sublimated gas stabilized at a prescribed concentration can be fed into the post process.

In the invention, the container storing the solid material may be filled with an inert gas (such as dilution gas) in advance before heating or may be in a vacuum state. The container storing the solid material has a configuration in which the sublimated gas obtained from the solid material by heating the container is fed into the vacuum container, the solid material is further sublimated by continuously heating, and the sublimated gas is fed into the vacuum container when the pressure inside the container becomes a prescribed value (such as saturated vapor pressure); and this process is repeated.

In the invention, the sublimated gas supply system may have a configuration in which

the number of each of the container, the container heating unit, and the container pressure gauge is n (n is 1 or more),

the number of the vacuum container is 2 times or more n,

the number of the pressure gauge is 2 times or more n, and

the flow amount control unit controls the flow amount of the dilution gas before the dilution gas is introduced into each of 2 times or more n of the vacuum containers.

According to this configuration, a supply system configured with the necessary number of devices corresponding to the post process can be constructed, and the sublimated gas with a stable concentration can be continuously supplied.

In the invention, the system configuration when n=1 will be shown.

A sublimated gas supply system includes:

a container for storing a solid material;

a container heating unit for heating the container so that a sublimated gas of the solid material is produced;

a container pressure gauge for measuring a pressure inside the container;

a first vacuum container configured so that the sublimated gas is introduced from the container in a state where a pressure of the sublimated gas is in a prescribed negative pressure range (in a vacuum state or a state of a prescribed negative pressure) when the pressure measured with the container pressure gauge is a saturated vapor pressure of the sublimated gas (or when the pressure of the sublimated gas inside the container is a prescribed value or more);

a first pressure gauge for measuring a pressure inside the first vacuum container;

a second vacuum container configured so that the sublimated gas is introduced from the container in a state where the pressure of the sublimated gas is in a prescribed negative pressure range (in a vacuum state or a state of a prescribed negative pressure) when the pressure measured with the container pressure gauge is a saturated vapor pressure of the sublimated gas (or when the pressure of the sublimated gas inside the container is a prescribed value or more);

a second pressure gauge for measuring a pressure inside the second vacuum container;

a sublimated gas lead-out line for leading out saturated vapor of the sublimated gas from the container to the first vacuum container or the second vacuum container in a switchable manner;

a dilution gas line for introducing dilution gas into the first vacuum container or the second vacuum container in a switchable manner;

a flow amount control unit for controlling a flow amount of the dilution gas so that a concentration of the sublimated gas in the dilution gas inside the first vacuum container is controlled to be a prescribed concentration based on the pressure inside the first vacuum container when the sublimated gas is introduced into the first vacuum container, and for controlling a flow amount of the dilution gas so that a concentration of the sublimated gas in the dilution gas inside the second vacuum container is controlled to be a prescribed concentration based on the pressure inside the second vacuum container when the sublimated gas is introduced into the second vacuum container;

a lead-out line for leading out the sublimated gas from the first vacuum container or the second vacuum container into the post process when the concentration of the sublimated gas in the dilution gas reaches the prescribed concentration in a switchable manner; and

a vacuum pump line that comprises a vacuum pump and makes the vacuum containers be in a vacuum state in a switchable manner.

According to this configuration, the sublimated gas can be fed from the container into the first vacuum container or the second vacuum container alternatively with two vacuum containers to one container corresponding to request of the post process. The dilution gas can be fed into the first and second vacuum containers with a single flow amount control unit to adjust the concentration of the sublimated gas inside the first and second vacuum containers. Further, the first and second vacuum containers can be made in a vacuum state with a single vacuum pump.

In the invention, the sublimated gas supply system may include a gas heating unit (such as a heat exchanger) that is arranged in the dilution gas line and controls a temperature of the dilution gas.

According to this configuration, the temperature of the dilution gas can be controlled to prevent or suppress decreases of the temperature of the vacuum container and the temperature of the sublimated gas inside the vacuum container, and therefore the precipitation of the sublimated solid material can be effectively prevented, and the concentration of the sublimated gas can be stabilized. The gas heating unit preferably controls the temperature of the dilution gas to be the same as the temperature of the sublimated gas.

In the invention, the temperatures of the devices configuring the system (such as vacuum containers and piping where the sublimated gas moves) may be controlled. Accordingly, the precipitation of the solid material due to a decrease of the temperature of the sublimated gas can be effectively prevented, and the concentration of the sublimated gas can be stabilized.

In the invention, the sublimated gas supply system may include:

a sublimated gas concentration calculation unit for calculating the concentration of the sublimated gas in the dilution gas inside the vacuum container from the pressure inside the vacuum container measured from the pressure gauge; and

a monitor unit for monitoring the concentration of the sublimated gas calculated in the sublimated gas concentration calculation unit.

As another embodiment, the sublimated gas supply system may include a monitor unit for monitoring the concentration of the sublimated gas in the dilution gas detected by a concentration measurement unit (such as a thermal conductivity detector (TCD)) arranged in the lead-out line.

In the invention, the sublimated gas supply system may include:

a temperature indicator controller (TIC) for controlling a temperature of the container heating unit; and

a flowmeter that is arranged in the lead-out line and controls a flow amount of the sublimated gas.

Another aspect of the present invention provides a sublimated gas supply method for supplying a sublimated gas produced from a solid material to a post process, the method including:

a container heating step of heating a container so that the sublimated gas of the solid material stored in the container is produced;

a container pressure measurement step of measuring a pressure inside the container;

a buffer step of introducing the sublimated gas from the container into a vacuum container that is in a state of a prescribed negative pressure range (in a vacuum state or a state of a prescribed negative pressure) when the pressure measured in the container pressure measurement step is a saturated vapor pressure of the sublimated gas (or when the pressure of the sublimated gas inside the container is a prescribed value or more);

a flow amount control step of controlling a flow amount of the dilution gas so that a concentration of the sublimated gas in the dilution gas inside the vacuum container is controlled to be a prescribed concentration based on the pressure inside the vacuum container when the sublimated gas is introduced into the vacuum container;

a lead-out step of leading out the sublimated gas from the vacuum container into the post process when the concentration of the sublimated gas in the dilution gas reaches the prescribed concentration; and

a vacuum step of making the vacuum container be in a vacuum state.

In the above description, the sublimated gas supply method may have a configuration in which the dilution gas is fed into the vacuum container every time the sublimated gas is fed from the container into the vacuum container (every time the buffer step is performed) to adjust the concentration of the sublimated gas, the sublimated gas (including the dilution gas) having a prescribed concentration is fed from the vacuum container into the post process, the vacuum container is then made to have a prescribed negative pressure state (such as a vacuum state), and the next sublimated gas is fed from the container into the vacuum container.

In the above description, the sublimated gas supply method may also have a configuration in which the dilution gas is fed into the vacuum container after the sublimated gas is fed from the container into the vacuum container two times or more (after the buffer step is performed two times or more) to adjust the concentration of the sublimated gas, the sublimated gas (including the dilution gas) having a prescribed concentration is fed from the vacuum container into the post process, the vacuum container is then made to have a prescribed negative pressure state (such as a vacuum state), and the next sublimated gas is fed from the container into the vacuum container (two times or more).

In the invention, where the container is one and the vacuum containers are two, the flow amount control step may be completed in one vacuum container before the lead-out step is completed in the other vacuum container.

In the invention, the sublimated gas supply method may include a gas heating step of controlling a temperature of the dilution gas.

In the invention, the sublimated gas supply method may include:

a concentration calculation step of calculating the concentration of the sublimated gas in the dilution gas inside the vacuum container from the pressure inside the vacuum container; and

a monitor step of monitoring the concentration of the sublimated gas calculated in the concentration calculation step.

As another embodiment, the sublimated gas supply method may include a monitor step of monitoring the concentration of the sublimated gas in the dilution gas detected by a concentration measurement unit (such as a thermal conductivity detector (TCD)) arranged in the lead-out line for leading out the sublimated gas from the vacuum container to the post process.

### BRIEF DESCRIPTION OF THE DRAWINGS

FIG. 1 illustrates an explanatory diagram showing an outline of a sublimated gas supply system according to Embodiment 1; and

FIG. 2 illustrates an explanatory diagram showing an outline of a sublimated gas supply system according to Embodiment 2.

### DETAILED DESCRIPTION OF THE PREFERRED EMBODIMENTS

Several embodiments of the present invention will be explained below. The embodiments explained below are to explain one example of the present invention. The present invention is not limited to the following embodiments at all and includes various types of modifications carried out within a scope where the gist of the present invention is not changed. All of the configurations explained below are not necessarily essential configurations of the present invention.

### Embodiment 1

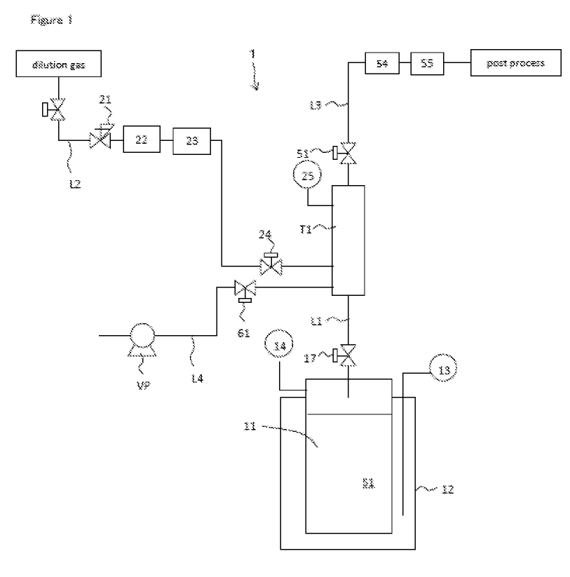

FIG. 1 illustrates an outline of a sublimated gas supply system 1. The sublimated gas supply system of the present embodiment is configured with one vacuum container per container.

A solid material S1 is stored in a container 11. The container 11 includes a single or a plurality of trays, which may be a tray type container in which the solid material S1 is placed on a tray or may be a tray-less container in which the solid material S1 is placed as it is inside the container without a tray.

A heater 12 (corresponding to a container heating unit) directly heats the container 11 to produce a sublimated gas of the solid material S1. As the container heating unit, instead of the heater 12, an oven type container heating unit may be used in heating the container 11 placed in an oven. A heater temperature regulator 13 measures a temperature of the heater 12 and controls the heater temperature. A gate valve 17 is closed to seal the container 11, and the container 11 is heated to generate a sublimated gas. A container pressure gauge 14 measures a pressure inside the container 11.

The sublimated gas is introduced from the container 11 into a vacuum container T1. Before the sublimated gas is introduced, the vacuum container T1 is kept in a vacuum state (substantially vacuum state). A first pressure gauge 25 measures a pressure inside the vacuum container T1. A vacuum pump VP is connected to the vacuum container T1 through a gate valve 61. The gate valve 61 is opened to operate the vacuum pump VP, and the vacuum container T1 is made to be in a vacuum state. At this time, whether or not the pressure inside the vacuum container T1 reaches a vacuum state may be determined from the value measured with the first pressure gauge 25. The vacuum pump VP is operated only when a line L4 is opened, and all of gate valves (17, 24, 51) of other lines (L1, L2, L3) connected to the vacuum container T1 are closed.

When the pressure measured with the container pressure gauge 14 is the saturated vapor pressure of the sublimated gas, the gate valve 17 is opened while the gate valves (24, 51, 61) of the other lines (L2, L3, L4) connected to the vacuum container T1 are closed to introduce the sublimated gas from the container 11 into the vacuum container T1 in a vacuum state. When the pressure value of the first pressure gauge 25 reaches a constant pressure, it is determined that the transfer of the saturated vapor of the sublimated gas is completed, and the gate valve 17 may be closed. When the pressure value of the container pressure gauge 14 reaches a prescribed pressure or less, it is determined that the transfer of the saturated vapor of the sublimated gas is completed, and the gate valve 17 may be closed. Even while the sublimated gas is moved or even after the gate valve 17 is closed, the container 11 is or may be heated with the heater 12, and the sublimated gas is produced inside the container 11.

A dilution gas line L2 that introduces a dilution gas is connected to the vacuum container T1. An inert gas is used as the dilution gas. For example, an inert gas such as nitrogen gas or a noble gas such as argon gas may be used as the dilution gas. Hydrogen gas having good thermal conductivity may be also used.

For example, a pressure control valve 21, a mass flow controller 22, a heat exchanger 23, and the gate valve 24 are arranged in the dilution gas line L2. The pressure control valve 21 has a function of making the pressure inside the container 11 be constant. The mass flow controller 22 measures a flow amount of the dilution gas and controls the flow amount. The mass flow controller 22 may control the flow amount of the dilution gas based on the pressure measured with the first pressure gauge 25 or the concentration of the sublimated gas inside the first vacuum container calculated in a sublimated gas concentration calculation unit. The heat exchanger 23 (corresponding to a gas heating unit) heats the dilution gas so that the temperature of the dilution gas becomes a prescribed temperature.

The sublimated gas inside the vacuum container T1 is in a saturated vapor state. The concentration of the sublimated gas is adjusted in the vacuum container T1 so as to be the concentration of the sublimated gas desired in the post process. Specifically, the gate valve 24 is opened while the gate valves of the other lines (L1, L3, L4) connected to the vacuum container T1 are closed. The dilution gas is fed into the vacuum container T1 while controlling the flow amount of the dilution gas with the mass flow controller 22.

The sublimated gas concentration calculation unit (not shown) calculates a concentration of a sublimated gas in the dilution gas inside the vacuum container T1 based on the pressure measured with the first pressure gauge 25. For example, the concentration of the sublimated gas may be obtained from a correlation between the concentration and the pressure set in advance corresponding each solid material. A monitor unit (not shown) has a function of monitoring the concentration of the sublimated gas calculated by the sublimated gas concentration calculation unit, and the monitor unit may send the data to external devices or display the data on a monitor. Once the concentration of the sublimated gas reaches a prescribed concentration, feeding of the dilution gas may be stopped, or once a pressure measured with a first pressure gauge 25 reaches a prescribed pressure, feeding of the dilution gas may be stopped. The concentration of the sublimated gas may be converted from the “prescribed pressure”. The above stopping of the feeding of the dilution gas is performed by closing the gate valve 24.

The concentration of the sublimated gas may be calculated as follows.

If P1 represents the pressure of the vacuum container T1 measured with the first pressure gauge 25 when the sublimated gas is introduced and P2 represents the pressure of the vacuum container T1 measured with the first pressure gauge 25 after the dilution gas is introduced, the concentration of the sublimated gas is obtained from the following formula:

Concentration of sublimated gas [Vol %]=100=(P1/P2).

The dilution gas may be introduced into the vacuum container T1 every time the sublimated gas is introduced from the container 11, after a prescribed number of times of the introduction of the sublimated gas, or after the sublimated gas is fed from the container 11 until the pressure inside the vacuum container T1 exceeds a prescribed pressure.

A lead-out line L3 is provided for leading out the sublimated gas from the vacuum container T1 to the post process. When the concentration of the sublimated gas in the dilution gas reaches a prescribed concentration, the sublimated gas is fed from the vacuum container T1 into the post process through the lead-out line L3. The gate valve 51 is opened while the gate valves of the other lines (L1, L2, L3) connected to the vacuum container T1 are closed. A mass flow meter 55 (corresponding to a flow meter) is arranged in the lead-out line L3 and controls the flow amount of the sublimated gas. A thermal conductivity detector 54 is arranged in the lead-out line L3. The system may have a configuration in which the thermal conductivity detector 54 detects the concentration of the sublimated gas in the dilution gas and the monitor unit (not shown) monitors the concentration of the sublimated gas.

After the sublimated gas is fed from the vacuum container T1, the gate valve 51 of the lead-out line L3 is closed. When the pressure measured with the first pressure gage 25 becomes a prescribed pressure or less, it may be determined that the feeding of the sublimated gas is completed. In order to make the vacuum container T1 be in a vacuum state, the gate valve 61 is opened while the gate valves of the other lines (L1, L2, L3) connected to the vacuum container T1 are closed, and the vacuum pump VP is operated. The vacuum container T1 is made to be in a vacuum state, and in the same as above, the processing is repeated of moving the sublimated gas inside the container 11 into the vacuum container T1.

Based on the pressures measured with the pressure gauges such as the container pressure gauge and the first pressure gauge, various types of control such as the opening and closing control of each gate valve, the determination whether or not the sublimated gas has a saturated vapor pressure, the determination of the timing for introducing the dilution gas, and the temperature control of the heat exchanger 23 (temperature control of the dilution gas) may be performed by a main control unit (not shown) or a control module assigned for each type of control.

### Embodiment 2

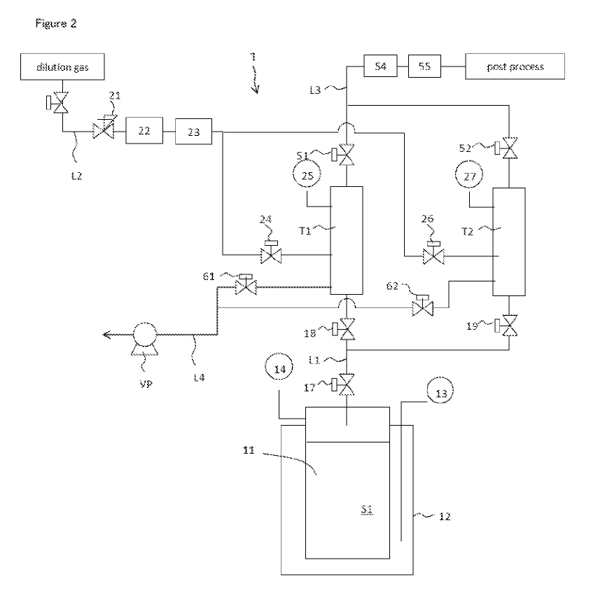

As shown in FIG. 2, the sublimated gas supply system of Embodiment 2 is configured with two vacuum containers per container. Because the components denoted by the same reference signs have the same configurations as described in Embodiment 1, their explanations are omitted or briefly explained.

In Embodiment 2, before the leading-out of the sublimated gas from the first vacuum container T1 to the post process is completed, the sublimated gas is fed from the container 11 into a second vacuum container T2, and the dilution gas is fed to adjust the concentration of the sublimated gas. After the adjustment of the concentration of the sublimated gas is completed and the feeding of the sublimated gas from the first vacuum container T1 into the post process is finished, the opening and closing of the gate valves is controlled to feed the sublimated gas from the second vacuum container T2 into the post process. On the other hand, before the leading out of the sublimated gas from the second vacuum container T2 to the post process is completed, the sublimated gas is fed from the container 11 into the first vacuum container T1, and the dilution gas is fed to adjust the concentration of the sublimated gas. After the adjustment of the concentration of the sublimated gas is completed and the feeding of the sublimated gas from the second vacuum container 12 into the post process is finished, the opening and closing of the gate valves is controlled to feed the sublimated gas from the first vacuum container T1 into the post process. Because this sublimated gas supply system has two vacuum containers to alternatively adjust the concentration of the sublimated gas with the dilution gas, the sublimated gas can be continuously supplied.

As described above, because the two vacuum containers are alternatively used, a sublimated gas lead-out line L1 has two sublines, and one gate valve (18, 19) is arranged in each of the two sublines. Further, the dilution gas line L2 for introducing the dilution gas into the first and second vacuum containers T1 and T2 has two sublines, and one gate valve (24, 26) is arranged in each of the two sublines. The lead-out line L3 for sending the sublimated gas from the vacuum container to the post process has two sublines, and one gate valve (51, 52) is arranged in each of the two sublines.

Before the leading out of the sublimated gas whose concentration is adjusted from the first vacuum container T1 to the post process is completed, the following processing is performed in the second vacuum container T2.

When the pressure measured with the container pressure gauge 14 is the saturated vapor pressure of the sublimated gas, the gate valves 17 and 19 are opened while the gate valves (26, 52, 62) of the other lines (L2, L3, L4) connected to the second vacuum container T2 and the gate valve 18 are closed to introduce the sublimated gas from the container 11 into the second vacuum container T2 in a vacuum state. Next, the concentration of the sublimated gas is adjusted in the second vacuum container T2 so as to be a desired concentration in the post process. The gate valve 26 is opened while the gate valves (19, 52, 62) of the other lines (L1, L3, L4) connected to the second vacuum container T2 and the gate valve 24 are closed. The dilution gas is fed into the second vacuum container T2 while controlling the flow amount of the dilution gas with the mass flow controller 22.

The sublimated gas concentration calculation unit (not shown) calculates a concentration of a sublimated gas in the dilution gas inside the second vacuum container T2 based on the pressure measured with the second pressure gauge 27. A monitor unit (not shown) has a function of monitoring the concentration of the sublimated gas calculated by the sublimated gas concentration calculation unit, and the monitor unit may send the data to external devices or display the data on a monitor. The monitor unit (not shown) may have a configuration of monitoring the concentration of the sublimated gas detected by the thermal conductivity detector 54. Once the concentration of the sublimated gas reaches a prescribed concentration, feeding of the dilution gas may be stopped, or once a pressure measured with the second pressure gauge 27 reaches a prescribed pressure, feeding of the dilution gas may be stopped. The concentration of the sublimated gas may be converted from the “prescribed pressure”. The above stopping of the feeding of the dilution gas is performed by closing the gate valve 26.

The dilution gas may be introduced into the second vacuum container T2 every time the sublimated gas is introduced from the container 11, after a prescribed number of times of the introduction of the sublimated gas, or after the sublimated gas is fed from the container 11 until the pressure inside the second vacuum container T2 exceeds a prescribed pressure.

When the processing of feeding the sublimated gas into the post process is completed in the first vacuum container T1, the gate valve 51 of the lead-out line L3 is closed, and the gate valve 52 is opened. Accordingly, the sublimated gas whose concentration is adjusted can be fed from the second vacuum container T2 into the post process through the lead-out line L3.

Before the leading out of the sublimated gas whose concentration is adjusted from the second vacuum container T2 to the post process is completed, the following processing is performed in the first vacuum container T1. The gate valve 51 is closed, and the gate valve 61 is opened to make the first vacuum container T1 be in a vacuum state using the vacuum pump VP.

When the pressure measured with the container pressure gauge 14 is the saturated vapor pressure of the sublimated gas, the gate valves 17 and 18 are opened while the gate valves (24, 51, 61) of the other lines (L2, L3, L4) connected to the first vacuum container T1 and the gate valve 19 are closed to introduce the sublimated gas from the container 11 into the first vacuum container T1 in a vacuum state. Next, the concentration of the sublimated gas is adjusted in the first vacuum container T1 so as to be a concentration desired in the post process. The gate valve 24 is opened while the gate valves (18, 51, 61) of the other lines (L1, L3, and L4) connected to the first vacuum container T1 and the gate valve 26 are closed. The dilution gas is fed into the first vacuum container T1 while controlling the flow amount of the dilution gas with the mass flow controller 22.

The sublimated gas concentration calculation unit (not shown) calculates the concentration of the sublimated gas in the dilution gas inside the first vacuum container T1 based on the pressure measured with the first pressure gauge 25. The monitor unit (not shown) has a function of monitoring the concentration of the sublimated gas calculated by the sublimated gas concentration calculation unit, and the monitor unit may send the data to external devices or display the data on a monitor. The monitor unit (not shown) may have a configuration of monitoring the concentration of the sublimated gas detected by the thermal conductivity detector 54. Once the concentration of the sublimated gas reaches a prescribed concentration, feeding of the dilution gas may be stopped, or once the pressure measured by the first pressure gauge 25 reaches a prescribed pressure, feeding of the dilution gas may be stopped. The concentration of the sublimated gas may be converted from the “prescribed pressure”. The above stopping of the feeding of the dilution gas is performed by closing the gate valve 24.

The dilution gas may be introduced into the first vacuum container T1 every time the sublimated gas is introduced from the container 11, after a prescribed number of times of the introduction of the sublimated gas, or after the sublimated gas is fed from the container 11 until the pressure inside the first vacuum container T1 exceeds a prescribed pressure.

When the processing of feeding the sublimated gas to the post process is completed in the second vacuum container T2, the gate valve 52 of the lead-out line L3 is closed, and the gate valve 51 is opened. Accordingly, the sublimated gas whose concentration is adjusted can be fed from the first vacuum container T1 into the post process through the lead-out line L3. Then, the gate valve 52 is closed, and the gate valve 62 is opened to make the second vacuum container T2 be in a vacuum state using the vacuum pump VP. The above processing is repeated.

### Embodiment 3

A system can be constructed which has a plurality of the configurations described in Embodiment 1 or Embodiment 2 as one configuration unit. Accordingly, the system can respond to the requirements of the post process, the characteristics of the solid material, and the miniaturization of the container.

### Embodiment 4

The present embodiment involves the sublimated gas supply method.

The sublimated gas supply method for supplying a sublimated gas produced from a solid material to a post process includes:

a container heating step of heating a container so that the sublimated gas of the solid material stored in the container is produced;

a container pressure measurement step of measuring a pressure inside the container;

a buffer step of introducing the sublimated gas from the container into a vacuum container that is in a state of a prescribed negative pressure range (in a vacuum state or a state of a prescribed negative pressure) when the pressure measured in the container pressure measurement step is a saturated vapor pressure of the sublimated gas (or when the pressure of the sublimated gas inside the container is a prescribed value or more);

a flow amount control step of controlling a flow amount of the dilution gas so that a concentration of the sublimated gas in the dilution gas inside the vacuum container is controlled to be a prescribed concentration based on the pressure inside the vacuum container when the sublimated gas is introduced into the vacuum container;

a lead-out step of leading out the sublimated gas from the vacuum container into the post process when the concentration of the sublimated gas in the dilution gas reaches the prescribed concentration; and

a vacuum step of making the vacuum container be in a vacuum state.

In the case where the container is one and the vacuum containers are two, the flow amount control step may be completed in one vacuum container before the lead-out step is completed in the other vacuum container. The sublimated gas supply method may include a gas heating step of controlling a temperature of the dilution gas. Further, the sublimated gas supply method may include a concentration calculation step of calculating the concentration of the sublimated gas in the dilution gas inside the vacuum container from the pressure inside the vacuum container; and a monitor step of monitoring the concentration of the sublimated gas calculated in the concentration calculation step. The sublimated gas supply method may include a monitor step of monitoring the concentration of the sublimated gas in the dilution gas detected by a concentration measurement unit (such as a thermal conductivity detector (TCD)) arranged in the lead-out line for leading out the sublimated gas from the vacuum container to the post process.

### Other Embodiments

In the above-described embodiments, the sublimated gas having a saturated vapor pressure is fed from the container into the vacuum container. However, the invention is not limited thereto, and the sublimated gas may be fed from the container into the vacuum container when the pressure of the sublimated gas inside the container is a saturated vapor pressure or a prescribed pressure or more.

In the above-described embodiments, the sublimated gas is fed into the vacuum container under a vacuum state. However, the invention is not limited thereto, and the invention may have a configuration in which the sublimated gas is introduced under a substantial vacuum state or a state in which the inner pressure is a prescribed negative pressure.

The flow amount control unit (mass flow controller) has a configuration in which the flow amount of the dilution gas is controlled so that the concentration of the sublimated gas in the dilution gas inside the vacuum container is controlled to be a prescribed concentration based on the pressure inside the vacuum container. However, the invention is not limited thereto, and the flow amount of the dilution gas may be controlled so that the concentration of the sublimated gas in the dilution gas inside the vacuum container is controlled to be a prescribed concentration based on the initial pressure before the sublimated gas is introduced into the vacuum container and the pressure inside the vacuum container. The flow amount may be controlled based on the inner pressure (initial pressure) of the vacuum container before the sublimated gas is introduced and the pressure fluctuation.

1-9. (canceled)

10. A sublimated gas supply system for supplying a sublimated gas produced from a solid material to a post process, the system comprising:
a container that stores a solid material;
a container heating unit that heats the container so that the sublimated gas of the solid material is produced;
a container pressure gauge that measures a pressure inside the container;
a vacuum container configured so that the sublimated gas is introduced from the container in a state where a pressure of the sublimated gas is in a prescribed negative pressure range when the pressure measured with the container pressure gauge is a saturated vapor pressure of the sublimated gas;
a dilution gas line that introduces a dilution gas into the vacuum container;
a pressure gauge that measures a pressure inside the vacuum container;
a flow amount control unit that controls a flow amount of the dilution gas so that a concentration of the sublimated gas in the dilution gas inside the vacuum container is controlled to be a prescribed concentration based on the pressure inside the vacuum container when the sublimated gas is introduced into the vacuum container;
a lead-out line that leads the sublimated gas from the vacuum container into the post process when the concentration of the sublimated gas in the dilution gas reaches the prescribed concentration; and
a vacuum pump that places the vacuum container in a vacuum state

11. The sublimated gas supply system according to claim 10, further comprising a gate valve between the container and the vacuum container that opens when the pressure measured with the container pressure gauge is the saturated vapor pressure of the sublimated gas.

12. The sublimated gas supply system according to claim 10, the system further comprising:
a gas heating unit that is arranged in the dilution gas line and controls a temperature of the dilution gas.

13. The sublimated gas supply system according to claim 10, the system further comprising:
a concentration measurement unit that is arranged in the lead-out line and measures the concentration of the sublimated gas in the dilution gas in the lead-out line; and
a monitor unit that monitors the concentration of the sublimated gas in the dilution gas detected by the concentration measurement unit.

14. The sublimated gas supply system according to claim 10, wherein
the number of each of the container, the container heating unit, and the container pressure gauge is n (n is 1 or more),
the number of the vacuum containers is 2 times or more n,
the number of the pressure gauges is 2 times or more n, and
the flow amount control unit controls the flow amount of the dilution gas introduced into each of 2 times or more n of the vacuum containers.

15. The sublimated gas supply system according to claim 14, the system further comprising:
a gas heating unit that is arranged in the dilution gas line and controls a temperature of the dilution gas.

16. The sublimated gas supply system according to claim 14, the system further comprising:
a concentration measurement unit that is arranged in the lead-out line and measures the concentration of the sublimated gas in the dilution gas in the lead-out line; and
a monitor unit that monitors the concentration of the sublimated gas in the dilution gas detected by the concentration measurement unit.

17. A sublimated gas supply system for supplying a sublimated gas produced from a solid material to a post process, the system comprising:
a container that stores a solid material;
a container heating unit that heats the container so that the sublimated gas of the solid material is produced;
a container pressure gauge that measures a pressure inside the container;
a first vacuum container configured so that the sublimated gas is introduced from the container in a state where a pressure of the sublimated gas is in a prescribed negative pressure range when the pressure measured with the container pressure gauge is a saturated vapor pressure of the sublimated gas;
a first pressure gauge that measures a pressure inside the first vacuum container;
a second vacuum container configured so that the sublimated gas is introduced from the container in a state where a pressure of the sublimated gas is in a prescribed negative pressure range when the pressure measured with the container pressure gauge is a saturated vapor pressure of the sublimated gas;
a second pressure gauge that measures a pressure inside the second vacuum container;
a sublimated gas lead-out line that leads the sublimated gas from the container to the first vacuum container or the second vacuum container in a switchable manner;
a dilution gas line that introduces a dilution gas into the first vacuum container or the second vacuum container in a switchable manner;
a flow amount control unit that controls a flow amount of the dilution gas so that a concentration of the sublimated gas in the dilution gas inside the first vacuum container is controlled to be a prescribed concentration based on the pressure inside the first vacuum container when the sublimated gas is introduced into the first vacuum container, and for controlling a flow amount of the dilution gas so that a concentration of the sublimated gas in the dilution gas inside the second vacuum container is controlled to be a prescribed concentration based on the pressure inside the second vacuum container when the sublimated gas is introduced into the second vacuum container;
a lead-out line that leads the sublimated gas from the first vacuum container or the second vacuum container into the post process when the concentration of the sublimated gas in the dilution gas reaches the prescribed concentration in a switchable manner; and
a vacuum pump line that comprises a vacuum pump and places the first or second vacuum container in a vacuum state in a switchable manner.

18. The sublimated gas supply system according to claim 17, further comprising a gate valve between the first and second vacuum container that opens when the pressure measured with the container pressure gauge is the saturated vapor pressure of the sublimated gas.

19. The sublimated gas supply system according to claim 17, the system further comprising:
a gas heating unit that is arranged in the dilution gas line and controls a temperature of the dilution gas.

20. The sublimated gas supply system according to claim 17, the system further comprising:
a concentration measurement unit that is arranged in the lead-out line and measures the concentration of the sublimated gas in the dilution gas in the lead-out line; and
a monitor unit that monitors the concentration of the sublimated gas in the dilution gas detected by the concentration measurement unit.

21. A sublimated gas supply method for supplying a sublimated gas produced from a solid material to a post process, the method comprising:
a container heating step of heating a container so that the sublimated gas of the solid material stored in the container is produced;
a container pressure measurement step of measuring a pressure inside the container;
a buffer step of (a) opening a gate valve and introducing the sublimated gas from the container into a vacuum container that is in a state of a prescribed negative pressure range when the pressure measured in the container pressure measurement step is a saturated vapor pressure of the sublimated gas and (b) closing the gate valve when (i) a pressure value of the vacuum container reaches a constant pressure or (ii) the pressure measured in the container pressure measurement step reaches a prescribed pressure or less;
a flow amount control step of controlling a flow amount of the dilution gas so that a concentration of the sublimated gas in the dilution gas inside the vacuum container is controlled to be a prescribed concentration based on the pressure inside the vacuum container when the sublimated gas is introduced into the vacuum container;
a lead-out step of leading the sublimated gas from the vacuum container into the post process when the concentration of the sublimated gas in the dilution gas reaches the prescribed concentration; and
a vacuum step of placing the vacuum container in a vacuum state.

22. The sublimated gas supply method according to claim 21, wherein the container is one and the vacuum containers are two, the flow amount control step is completed in one vacuum container before the lead-out step is completed in the other vacuum container.

23. The sublimated gas supply method according to claim 21, the method comprising a gas heating step of controlling a temperature of the dilution gas.

24. The sublimated gas supply method according to claim 21, the method comprising a monitor step of monitoring the concentration of the sublimated gas in the dilution gas detected by a concentration measurement unit arranged in the lead-out line for leading the sublimated gas from the vacuum container to the post process.
